(19) United States
(12) Patent Application Publication
(10) Pub. No.: US 2013/0146966 A1
(43) Pub. Date: Jun. 13, 2013

(54) SEMICONDUCTOR STRUCTURE WITH ENHANCED CAP AND FABRICATION METHOD THEREOF

(71) Applicant: Chia-Yen Ho, New Taipei City (TW)

(72) Inventor: Chia-Yen Ho, New Taipei City (TW)

(21) Appl. No.: 13/313,016

(22) Filed: Dec. 7, 2011

(51) Int. Cl. H01L 29/78

(52) U.S. Cl. 257/330; 257/288; 257/E29.255; 257/E29.262

(57) ABSTRACT

A semiconductor structure includes a substrate, a feature on the substrate, a spacer on a sidewall surface of the feature, and an enhanced cap disposed on an upper surface of the spacer. The enhanced cap compensates the thinner upper portion of the spacer.

### BACKGROUND OF THE INVENTION

1. Field of the Invention

The present invention relates generally to semiconductor devices and, more particularly, to a fine semiconductor structure with an enhanced cap, and a fabrication method thereof.

2. Description of the Prior Art

A recessed channel access transistor (RCAT) device for high-density dynamic random access memory (DRAM) is known in the art. Generally, an RCAT device has a gate oxide layer formed on sidewalls and the bottom surface of a recess etched into a substrate, where a conductive substance or recessed gate fills the recess, contrary to a planar gate type transistor having a gate electrode formed on a planar surface of a substrate. Therefore, the integration of the recessed-gate transistor can be increased.

As the size of semiconductor devices shrinks, the space between semiconductor features such as gates also shrinks. Hence, there arises a problem of sidewall spacer shaving or insufficient bottom space between gates. As the design rule of the semiconductor device shrinks to 70 nm or less, the thickness control of the sidewall spacer, typically silicon nitride, becomes critical. It is highly desirable to make sidewall spacers as thin as possible to thereby increase the space between gates without suffering from the bridging between the gate conductor and the adjacent source/drain contact.

### SUMMARY OF THE INVENTION

It is one object of the present invention to provide an improved fine semiconductor structures such as gate conductor structures with wider bottom space between gates particularly in the DRAM array region.

It is another object of the present invention to provide an improved fine semiconductor structures such as gate conductor structures to prevent or alleviate sidewall spacer shaving.

In accordance with one embodiment, a semiconductor structure includes a substrate, a feature on the substrate, a spacer on a sidewall surface of the feature, and an enhanced cap disposed on an upper surface of the spacer.

In accordance with another embodiment, a recessed gate structure includes a substrate having thereon a recess, a feature disposed on the substrate and filling into the recess, a spacer on a sidewall surface of the feature, and an enhanced cap disposed on an upper surface of the spacer.

In accordance with still another embodiment, a recessed gate structure includes a substrate having thereon a recess, a feature disposed on the substrate and filling into the recess, a first spacer on a sidewall surface of the feature, a corner oxide between the first spacer, the feature and the substrate, a second spacer on the first spacer and the corner oxide, and an enhanced cap disposed on an upper surface of the second spacer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a schematic diagram illustrating a fine semiconductor structure with an enhanced cap in accordance with one embodiment of the invention;

FIG. 2 is a schematic diagram illustrating a recessed gate structure with an enhanced cap in accordance with another embodiment of the invention;

FIG. 3 is a schematic diagram illustrating a recessed gate structure with an enhanced cap in accordance with still another embodiment of the invention; and

FIGS. 4A-4I are schematic diagrams illustrating an exemplary method for fabricating a semiconductor device including the recessed gate structure with an enhanced cap of FIG. 3 according to this invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description, reference is made to the accompanying drawings, which form a part hereof, and in which is shown by way of illustration specific examples in which the embodiments may be practiced. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

With regard to the fabrication of transistors and integrated circuits, the term “major surface” refers to that surface of the semiconductor layer in and about which a plurality of transistors are fabricated, e.g., in a planar process. As used herein, the term “vertical” means substantially orthogonal with respect to the major surface. Typically, the major surface is along a <100> plane of a monocrystalline silicon layer on which the field-effect transistor devices are fabricated.

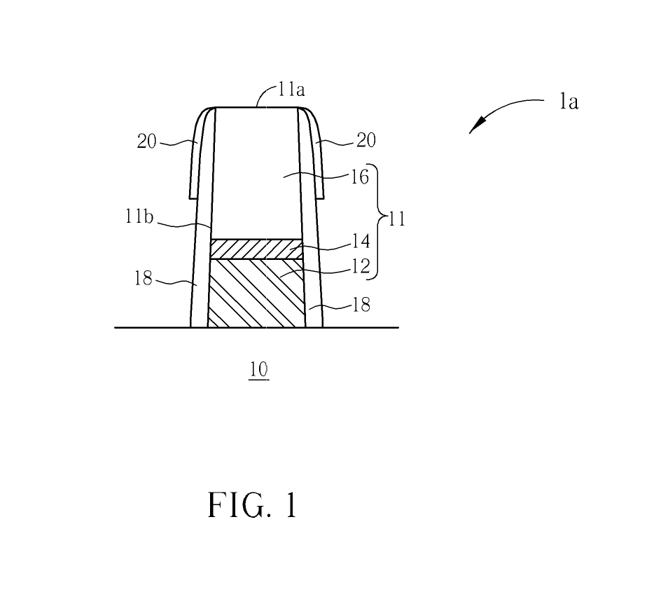

FIG. 1 is a schematic diagram illustrating a fine semiconductor structure 1a with an enhanced cap in accordance with one embodiment of the invention. The fine semiconductor structure 1a may be a planar gate structure, a digital line/word line structure, or any similar structure used in the semiconductor integrated circuits, and may have a dimension or line width of 70 nm or less, for example. As shown in FIG. 1, the fine semiconductor structure 1a is provided on a substrate 10. The substrate 10 may be a semiconductor substrate such as a silicon substrate or a SiGe substrate, a silicon-on-insulator (SOI) substrate, an epitaxial substrate, or the like. In some embodiments, at least one intervening layer (not shown) such as an inter-layer dielectric layer may be provided between the fine semiconductor structure 1a and the substrate 10. A feature 11 having a top surface 11a and sidewall surfaces 11b is formed on the substrate 10. The feature 11 may comprise an underlying conductor 12 such as metal or polysilicon and an overlying mask layer 16 such as a silicon nitride layer. The feature 11 may further comprise at least a material layer 14 such as a metal layer or a metal silicide layer between the mask layer 16 and the conductor 12. On the sidewall surfaces 11b, at least one pair of spacers 18 are formed. An enhanced cap 20 is formed merely on an upper surface of each of the spacers 18 to provide a mushroom-like profile. The enhanced cap 20 does not cover the top surface 11a. The enhanced cap 20 exposes a lower surface of the spacer 18. A step 22 is formed between the enhanced cap 20 and the underlying spacer 18 on the sidewall surface 11b of the feature 11. The enhanced cap 20 compensates the thinner upper portion of the spacer 18 and thus the invention can prevent or alleviate spacer shaving during a dry etching process. According to the embodiment, the enhanced cap 20 is composed of silicon nitride.

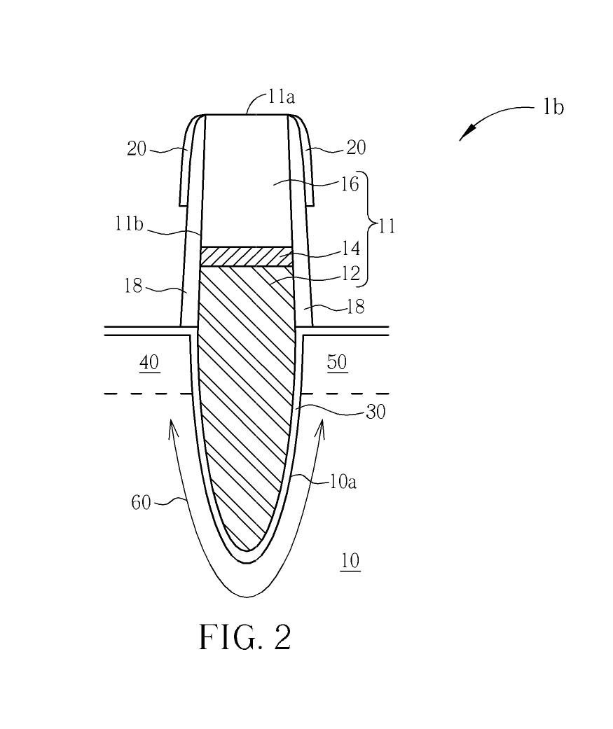

FIG. 2 is a schematic diagram illustrating a recessed gate structure 1b with an enhanced cap in accordance with another embodiment of the invention, wherein like numeral numbers designate like elements or layers. As shown in FIG. 2, the recessed gate structure 1b is fabricated on and in a substrate 10. Likewise, the substrate 10 may be a semiconductor substrate such as a silicon substrate or a SiGe substrate, an SOI substrate, an epitaxial substrate, or the like. A feature 11 having a top surface 11a and sidewall surfaces 11b is formed on the substrate 10. The feature 11 may comprise an underlying conductor 12 such as metal or polysilicon and an overlying mask layer 16 such as a silicon nitride layer stacked on the conductor 12. The feature 11 may further comprise at least a material layer 14 such as a metal layer or a metal silicide layer between the mask layer 16 and the conductor 12. The conductor 12 fills into a recess 10a formed in the substrate 10. An insulating layer 30 may be provided on the interior surface of the recess 10a. A source doping region 40 and a drain doping region 50 may be provided at two opposite sides of the recess 10a and define an U-shaped recessed channel 60 therebetween in the substrate 10. On the sidewall surfaces 11b, at least one pair of spacers 18 are formed. An enhanced cap 20 is formed on an upper surface of each of the spacers 18 to provide a mushroom-like profile. The enhanced cap 20 compensates the thinner upper portion of the spacer 18 and thus the invention can prevent or alleviate spacer shaving during a dry etching process. According to the embodiment, the enhanced cap 20 is composed of silicon nitride. Since the thickness of the upper portion of the spacer 18 is compensated by the enhanced cap 20, the bottom thickness of the spacer 18 can be reduced. Therefore, a bottom spacer between the adjacent features 11 can be wider.

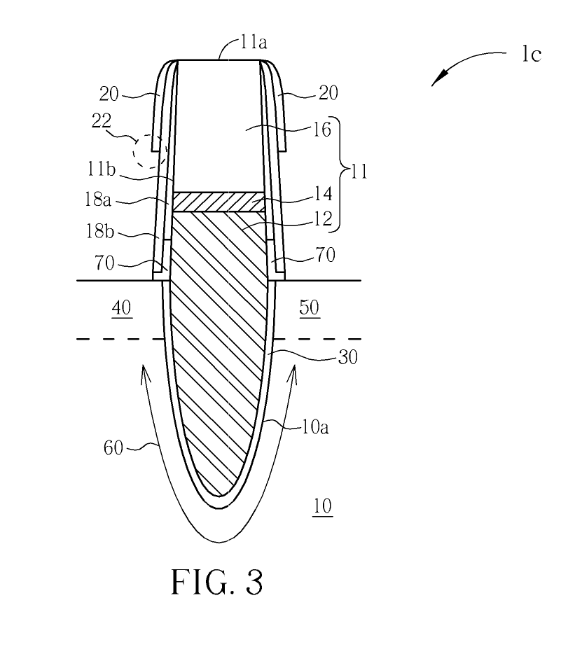

FIG. 3 is a schematic diagram illustrating a recessed gate structure 1c with an enhanced cap in accordance with still another embodiment of the invention, wherein like numeral numbers designate like elements or layers. As shown in FIG. 3, the recessed gate structure 1c is fabricated on and in a substrate 10. Likewise, the substrate 10 may be a semiconductor substrate such as a silicon substrate or a SiGe substrate, an SOI substrate, an epitaxial substrate, or the like. A feature 11 having a top surface 11a and sidewall surfaces 11b is formed on the substrate 10. The feature 11 may comprise an underlying conductor 12 such as metal or polysilicon and an overlying mask layer 16 such as a silicon nitride layer stacked on the conductor 12. The feature 11 may further comprise at least a material layer 14 such as a metal layer or a metal silicide layer between the mask layer 16 and the conductor 12. The conductor 12 fills into a recess 10a formed in the substrate 10. An insulating layer 30 may be provided on the interior surface of the recess 10a. A source doping region 40 and a drain doping region 50 may be provided at two opposite sides of the recess 10a and define an U-shaped recessed channel 60 therebetween in the substrate 10. On the sidewall surfaces 11b, a pair of first spacers 18a such as silicon nitride spacers are formed. An L-shaped corner oxide 70 is formed between the first spacer 18a, the conductor 12 and the substrate 10. The first spacer 18a is in direct contact with the L-shaped corner oxide 70 and is situated atop the L-shaped corner oxide 70. The L-shaped corner oxide 70 improves the isolation between the conductor 12 and the substrate 10 at the upper corner of the recess 10a, whereby the drain leakage can be reduced. A pair of second spacers 18b such as silicon nitride spacers are formed on the first spacers 18a and the L-shaped corner oxide 70. An enhanced cap 20 is formed on an upper surface of each of the second spacers 18b. The enhanced cap 20 compensates the thinner upper portion of the spacer 18b and thus the invention can prevent or alleviate spacer shaving during a dry etching process.

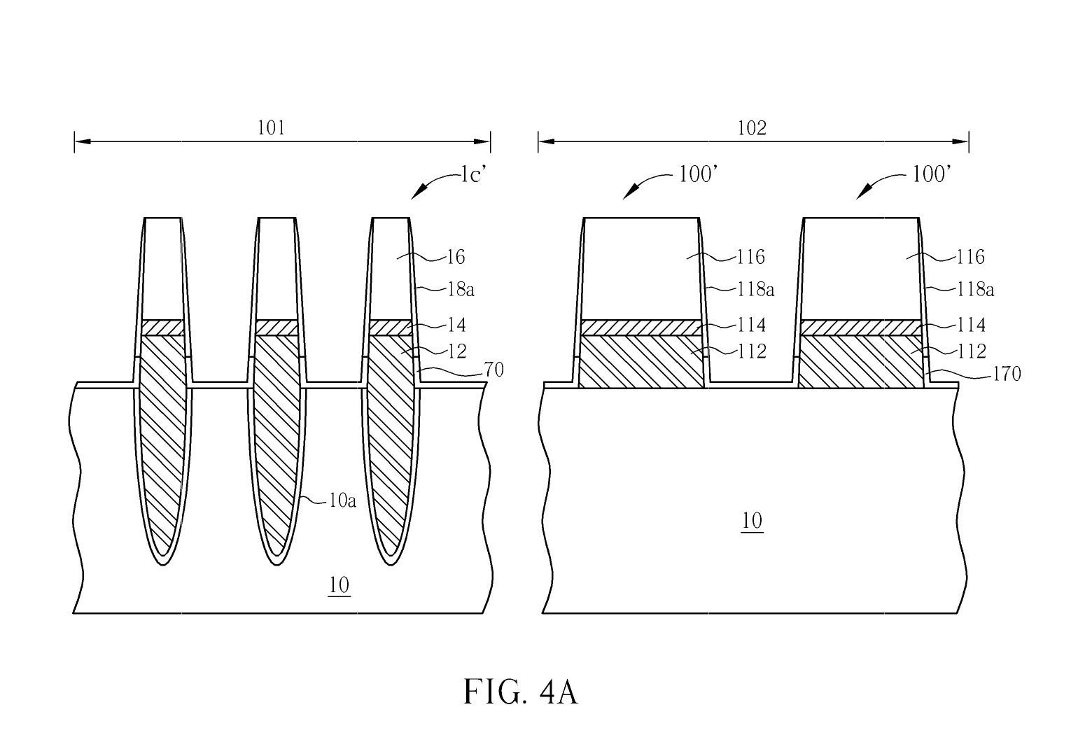

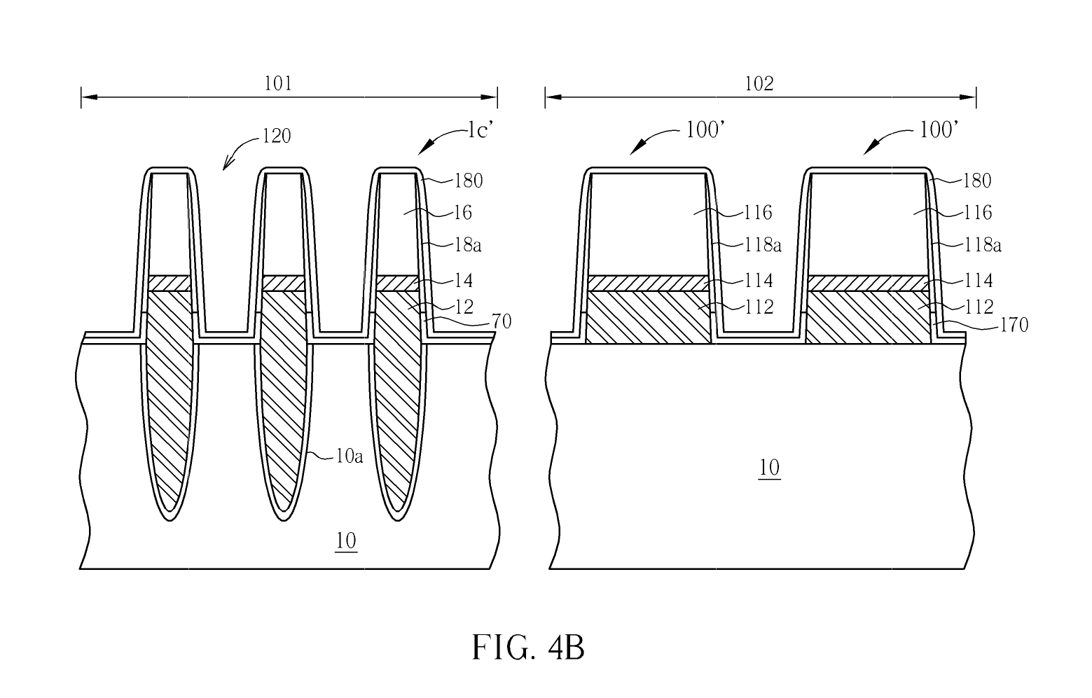

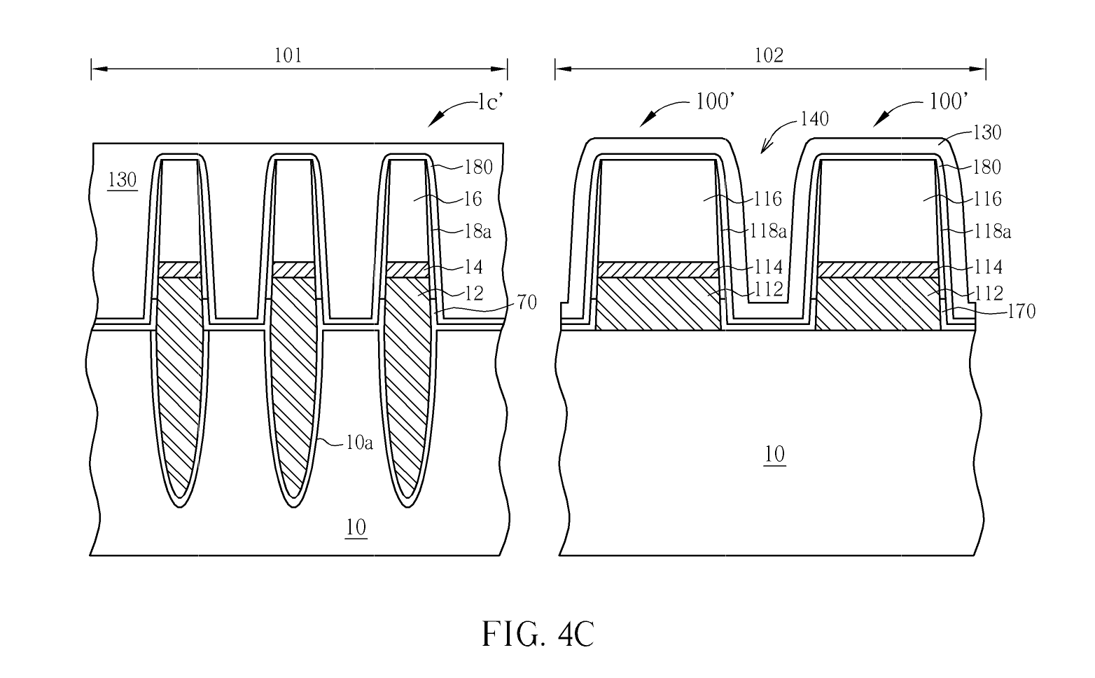

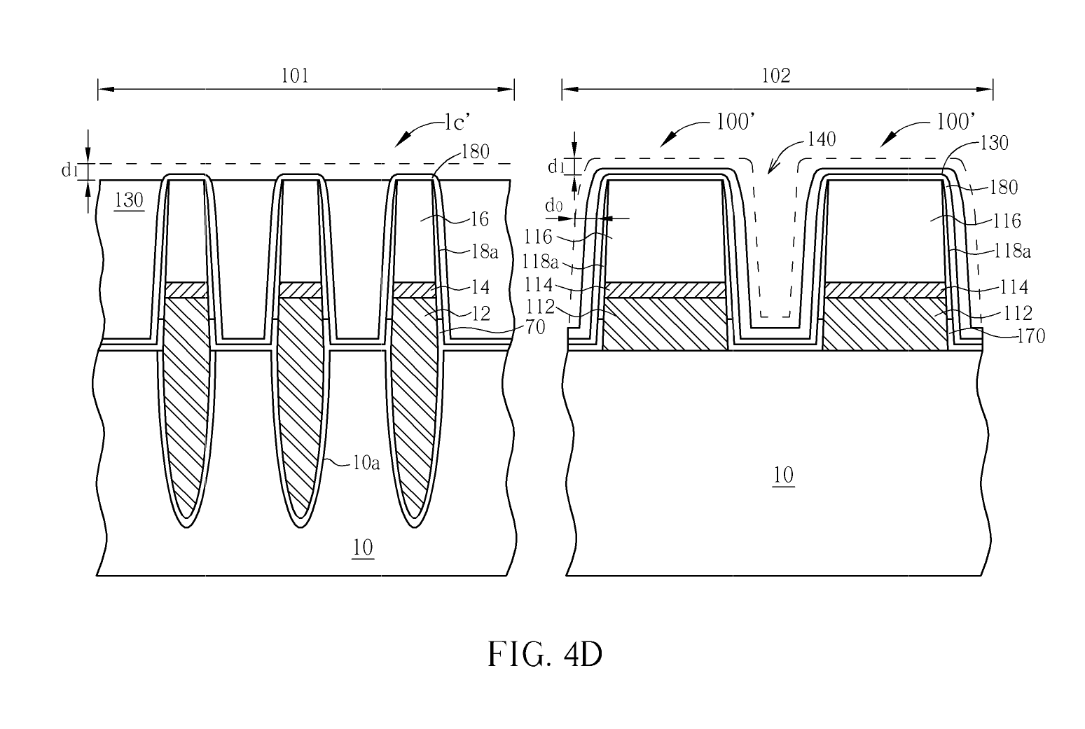

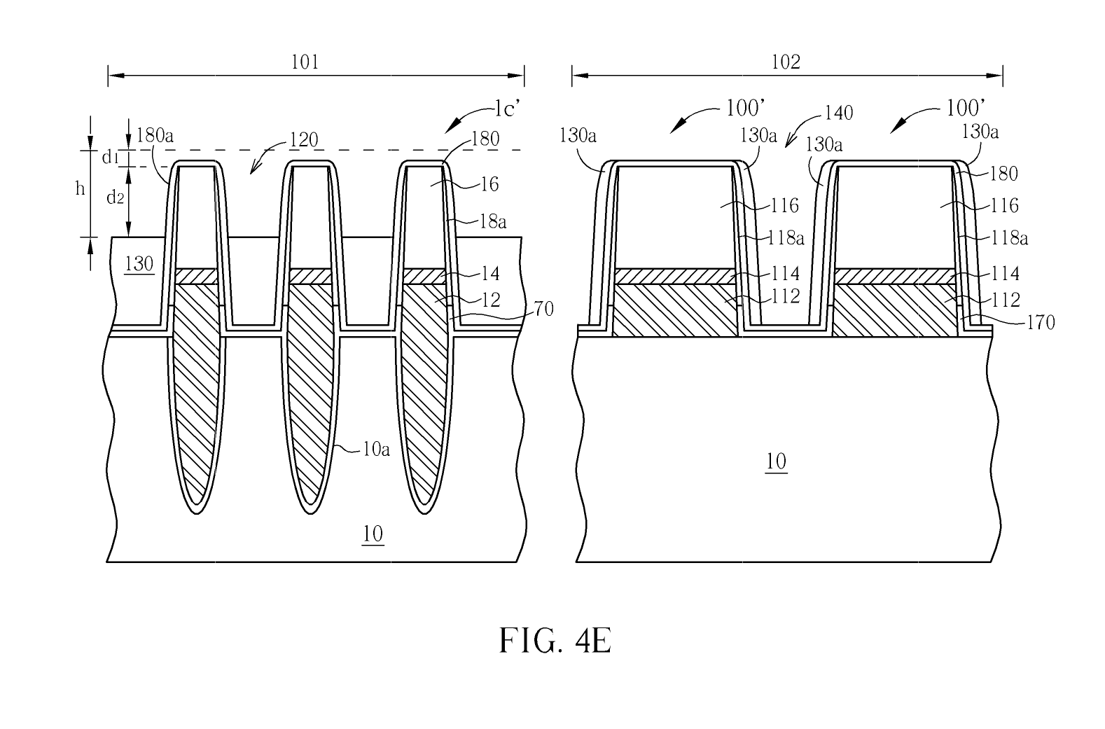

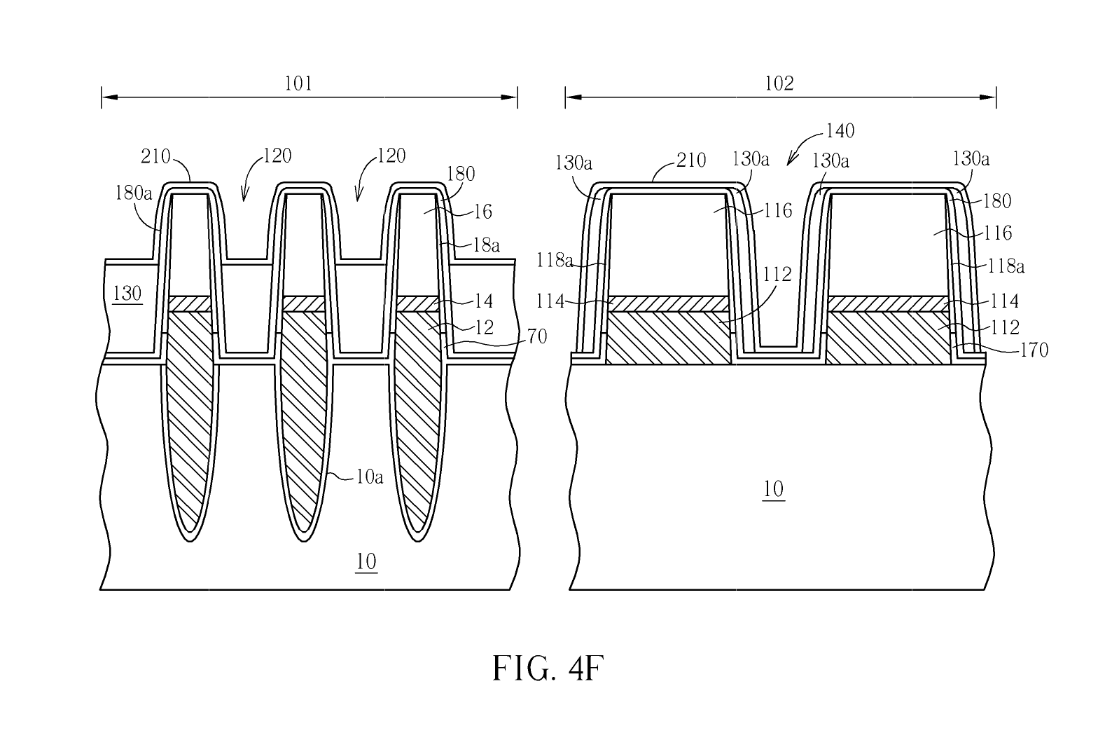

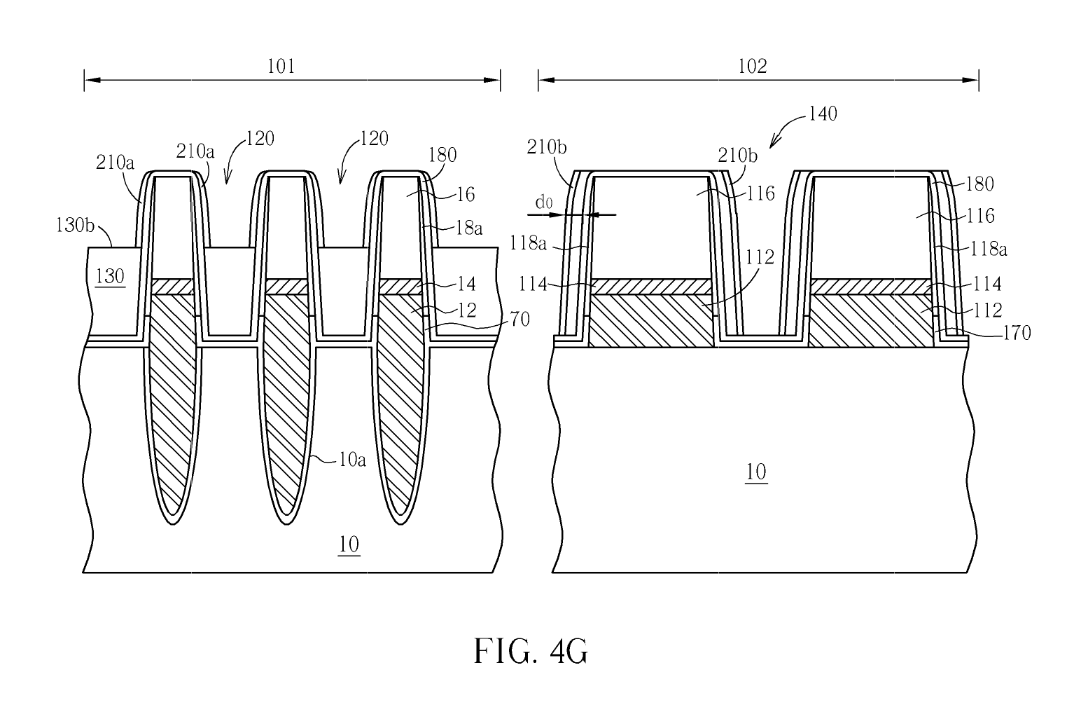

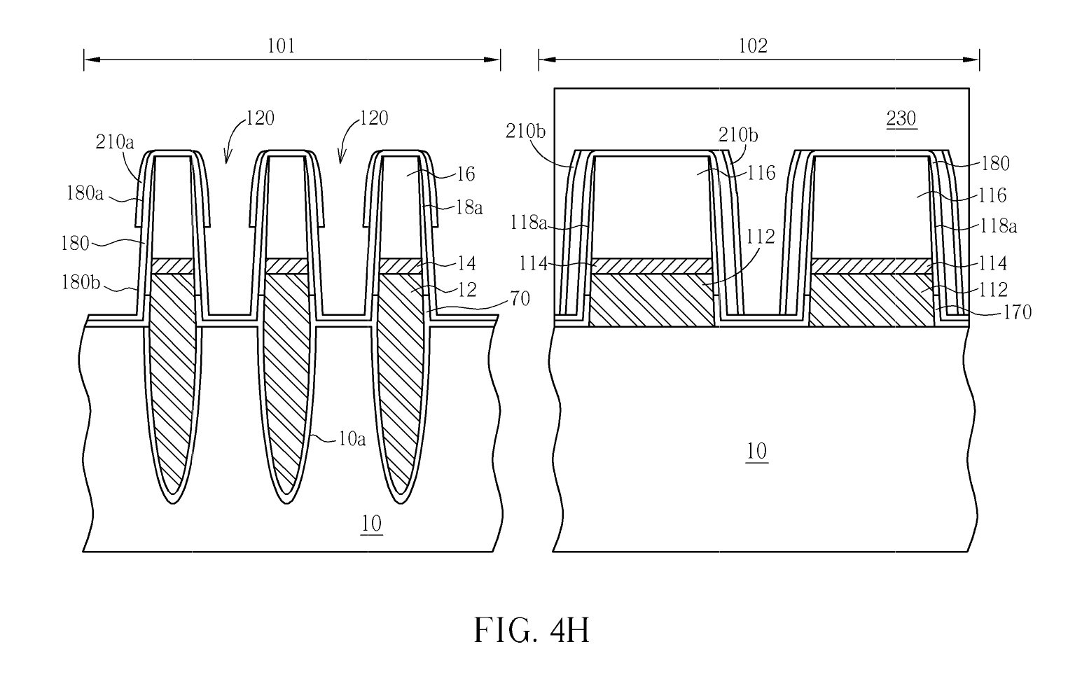

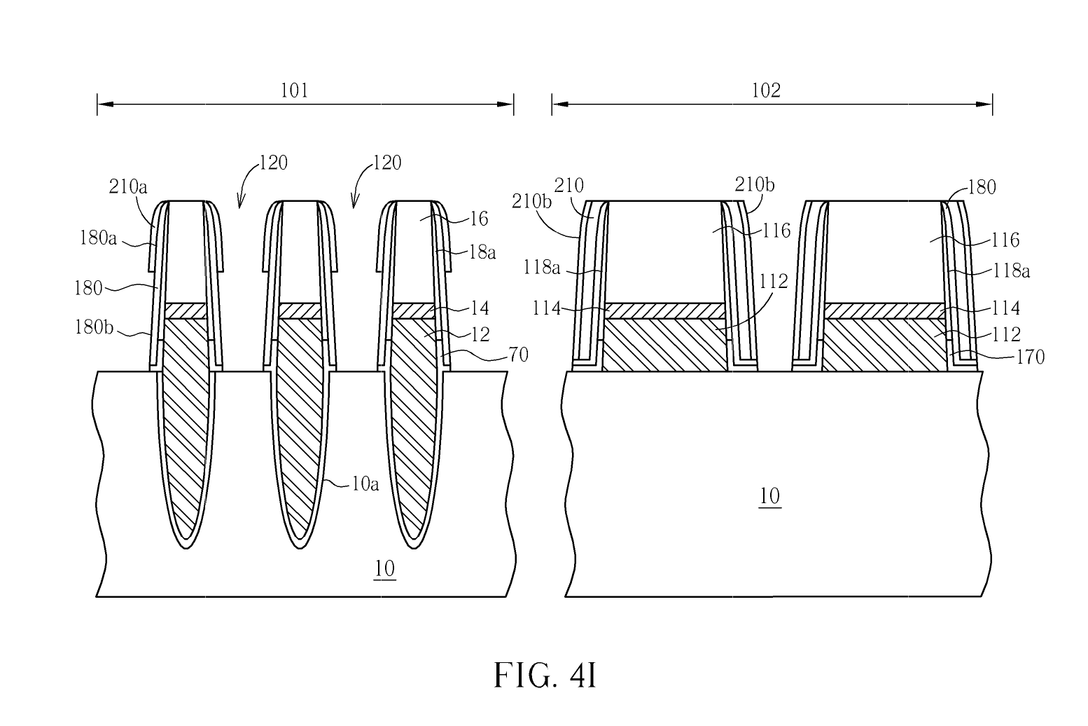

FIGS. 4A-4I are schematic diagrams illustrating an exemplary method for fabricating a semiconductor device including the recessed gate structure with an enhanced cap of FIG. 3 according to this invention, wherein like numeral numbers designate like elements or layers. As shown in FIG. 4A, a substrate 10, such as a silicon substrate, having a memory array region 101 and a peripheral circuit region 102 is provided. A plurality of recessed gate structures 1c′ are formed within the memory array region 101, and a plurality of gate structures 100′ are formed within the peripheral circuit region 102. Each of the recessed gate structures 1c′ comprises a conductor 12 such as metal or polysilicon and a mask layer 16 such as a silicon nitride layer stacked on the conductor 12. A material layer 14 such as a metal layer or a metal silicide layer may be provided between the mask layer 16 and the conductor 12. The conductor 12 fills into a recess 10a formed in the substrate 10. An insulating layer 30 may be provided on the interior surface of the recess 10a. Each of the recessed gate structures 1c′ further comprises a pair of first spacers 18a such as silicon nitride spacers. An L-shaped corner oxide 70 may be formed between the first spacer 18a, the conductor 12 and the substrate 10. Each of the gate structures 100′ comprises a conductor 112 such as metal or polysilicon and a mask layer 116 such as a silicon nitride layer stacked on the conductor 12. A material layer 114 such as a metal layer or a metal silicide layer may be provided between the mask layer 116 and the conductor 112. Each of the gate structures 100′ is provided with a pair of first spacers 118a such as silicon nitride spacers. An L-shaped corner oxide 170 may be formed between the first spacer 118a, the conductor 112 and the substrate 10. The gate structures 100′ may be planar gate structures having a gate channel that is substantially coplanar with the main surface of the substrate 10. In such case, a gate oxide layer (not shown) may be provided under the conductor 112.

As shown in FIG. 4B, a chemical vapor deposition (CVD) process is carried out to deposit a conformal spacer material layer 180 over the substrate 10. According to the embodiment of the invention, the spacer material layer 180 may comprise silicon nitride. The spacer material layer 180 conformally covers the sidewalls and top surfaces of the recessed gate structures 1c′ and the gate structures 100′. The spacer material layer 180 does not fill the space between the recessed gate structures 1c′. That is, after the deposition of the spacer material layer 180, a recess 120 is formed between the recessed gate structures 1c′.

As shown in FIG. 4C, a dielectric layer 130 such as silicon oxide is deposited over the substrate 10 in a blanket manner. The dielectric layer 130 fills up the recess 120 between the recessed gate structures 1c′ and covers the top surfaces of the recessed gate structures 1c′. However, the dielectric layer 130 does not fill up the space between the gate structures 100′ within the peripheral circuit region 102. A recess 140 is formed between the gate structures 100′ after the deposition of the dielectric layer 130.

As shown in FIG. 4D, an isotropic etching process such as a wet etching process is carried out to etch a top portion of the dielectric layer 130, thereby exposing a top portion of each of the recessed gate structures 1c′ within the memory array region 101. By performing the isotropic etching process, the thickness of the dielectric layer 130 in the peripheral circuit region 102 is also reduced to reach a desired spacer width of peripheral device. The reduced thickness d1 depends on the desired spacer width d0 of peripheral device.

As shown in FIG. 4E, an anisotropic dry etching process is then carried out to further etch away a top portion of the dielectric layer 130 from the memory array region 101, thereby exposing an upper sidewall surface 180a of the spacer material layer 180 in the recess 120. According to this embodiment, the reduced thickness d2 of the dielectric layer 130 in this stage is greater than d1. During the anisotropic dry etching process, the dielectric layer 130 in the peripheral circuit region 102 is also etched, in an anisotropic manner, using an etch chemistry selective to the underlying spacer material layer 180. After the anisotropic dry etching process, an oxide spacer 130a is formed on each side of the gate structures 100′ within the peripheral circuit region 102. The height h of the exposed recessed gate structures 1c′ from the top surface of the dielectric layer 130 equals to the combination of d1 and d2.

As shown in FIG. 4F, a CVD process is then carried out to deposit a thin cap layer 210 over the substrate 10. According to the embodiment, the thin cap layer 210 may comprise silicon nitride. The thin cap layer 210 conformally covers the exposed recessed gate structures 1c′ that protrudes from the top surface of the dielectric layer 130. The thin cap layer 210 also covers the top surface of the dielectric layer 130 in the recess 120. In the peripheral circuit region 102, the thin cap layer 210 covers the oxide spacers 130a of the gate structures 100′, as well as the gate structures 100′, in a conformal manner.

As shown in FIG. 4G, an anisotropic dry etching process is then carried out to etch the thin cap layer 210 in an anisotropic manner, thereby forming an enhanced spacer or cap 210a on each of the recessed gate structures 1c′ in the memory array region 101, and spacer 210b on the oxide spacer 130a of each of the gate structures 100′ in the peripheral circuit region 102. At this point, the top surface 130b of the dielectric layer 130 in the recess 120 is exposed. It is noteworthy that the combination of the thickness of the oxide spacer 130a and the thickness of the spacer 210b substantially equals to the desired spacer width d0 of peripheral device.

As shown in FIG. 4H, the peripheral circuit region 102 is masked by a patterned photoresist layer 230. The unmasked memory array region 101 is then subjected to a wet etching process to thereby remove the dielectric layer 130 from the recess 120. After the dielectric layer 130 is removed from the recess 120, the lower sidewall surface 180b of the spacer material layer 180 is exposed. At this point, the enhanced cap 210a merely covers the upper sidewall surface 180a of the spacer material layer 180.

As shown in FIG. 4I, after the wet etching process, the patterned photoresist layer 230 is removed. An anisotropic dry etching process is then performed to etch the spacer material layer 180 and corner oxide 70 at the bottom of the recesses 120 and 140, thereby exposing a portion of the substrate 10. Subsequently, the substrate 10 may be subjected to an ion implantation process to form a source/drain doping region (not shown) in the exposed portion of the substrate 10.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor structure, comprising:
a substrate;
a feature on the substrate;
a spacer on a sidewall surface of the feature; and
an enhanced cap disposed on an upper surface of the spacer, wherein the spacer and the enhanced cap are made of the same material.

2. The semiconductor structure according to claim 1 wherein the enhanced cap compensates thickness of an upper portion of the spacer.

3. The semiconductor structure according to claim 1 wherein the enhanced cap is disposed merely on an upper surface of the spacer and exposes a lower surface of the spacer.

4. The semiconductor structure according to claim 1 wherein there is a step between the enhanced cap and the spacer on the sidewall surface of the feature.

5. The semiconductor structure according to claim 1 wherein the feature comprises an underlying conductor and an overlying mask layer.

6. The semiconductor structure according to claim 5 wherein the conductor comprises metal or polysilicon.

7. The semiconductor structure according to claim 5 wherein the mask layer comprises a silicon nitride layer.

8. The semiconductor structure according to claim 1 wherein the spacer comprises silicon nitride.

9. The semiconductor structure according to claim 1 wherein the enhanced cap comprises silicon nitride.

10. A recessed gate structure, comprises:
a substrate having thereon a recess;
a feature disposed on the substrate and filling into the recess;
a spacer on a sidewall surface of the feature, wherein the spacer has an outer surface that is opposite to the sidewall surface; and
an enhanced cap disposed on an upper portion of the outer surface of the spacer.

11. The recessed gate structure according to claim 10 wherein the enhanced cap compensates thickness of an upper portion of the spacer.

12. The recessed gate structure according to claim 10 wherein the enhanced cap is disposed merely on an upper surface of the spacer and exposes a lower surface of the spacer.

13. The recessed gate structure according to claim 10 wherein there is a step between the enhanced cap and the spacer on the sidewall surface of the feature.

14. The recessed gate structure according to claim 10 wherein the feature comprises an underlying conductor and an overlying mask layer, wherein the conductor fills the recess.

15. The recessed gate structure according to claim 14 wherein the conductor comprises metal or polysilicon.

16. The recessed gate structure according to claim 14 wherein the mask layer comprises a silicon nitride layer.

17. The recessed gate structure according to claim 14 wherein an insulating layer is provided on interior surface of the recess to insulate the conductor from the substrate.

18. The recessed gate structure according to claim 10 wherein the spacer comprises silicon nitride.

19. The recessed gate structure according to claim 10 wherein the enhanced cap comprises silicon nitride.

20. A recessed gate structure, comprises:
a substrate having thereon a recess;
a feature disposed on the substrate and filling into the recess;
a first spacer on a sidewall surface of the feature;
a corner oxide between the first spacer, the feature and the substrate;
a second spacer on the first spacer and the corner oxide, wherein the second spacer has an outer surface that is opposite to the sidewall surface; and
an enhanced cap disposed on an upper portion of the outer surface of the second spacer.

21. The recessed gate structure according to claim 20 wherein the first spacer, the second spacer and the enhanced cap are all composed silicon nitride.

22. The recessed gate structure according to claim 20 wherein the enhanced cap compensates thickness of an upper portion of the spacer.

23. The recessed gate structure according to claim 20 wherein the enhanced cap is disposed merely on an upper surface of the spacer and exposes a lower surface of the spacer.

24. The recessed gate structure according to claim 20 wherein there is a step between the enhanced cap and the spacer on the sidewall surface of the feature.

25. The recessed gate structure according to claim 20 wherein the feature comprises an underlying conductor and an overlying mask layer, wherein the conductor fills the recess.

26. The recessed gate structure according to claim 25 wherein the conductor comprises metal or polysilicon.

27. The recessed gate structure according to claim 25 wherein the mask layer comprises a silicon nitride layer.

28. The recessed gate structure according to claim 25 wherein an insulating layer is provided on interior surface of the recess to insulate the conductor from the substrate.

29. The recessed gate structure according to claim 25 wherein the mask layer is a silicon nitride layer.
